(19) United States
(12) Patent Application Publication
(10) Pub. No.: US 2025/0046619 A1
(43) Pub. Date: Feb. 6, 2025

(54) METHOD OF MANUFACTURING SEMICONDUCTOR APPARATUS

(71) Applicant: Samsung Electronics Co., Ltd., Suwon-si (KR)

(72) Inventors: Guifu Yang, Suwon-si (KR); Sunghwan Jang, Suwon-si (KR); Sanghyeon Kim, Suwon-si (KR); Jinbum Kim, Suwon-si (KR); Hanhum Park, Suwon-si (KR); Sunguk Jang, Suwon-si (KR)

(21) Appl. No.: 18/791,926

(22) Filed: Aug. 1, 2024

(30) Foreign Application Priority Data
Aug. 4, 2023 (KR) 10-2023-0102286
Feb. 21, 2024 (KR) 10-2024-0025304

(51) Int. Cl. H01L 21/3115; H01L 21/033; H01L 21/311; H01L 21/3213

(52) U.S. Cl. CPC H01L 21/31155; H01L 21/0337; H01L 21/31144; H01L 21/32139

(57) ABSTRACT

A method of manufacturing a semiconductor apparatus includes forming a target layer, a bottom mask layer including a first mask, and a photoresist pattern, on a substrate; contracting the photoresist pattern; forming a mandrill bar on the first mask layer using the photoresist pattern that had been contracted; forming a conformal spacer layer on the first mask and the mandrill bar; etching the spacer layer such that at least a portion of the first mask is free of the spacer layer; forming a sacrificial layer on the at least the portion of the first mask; forming a hard-mask bar by etching the spacer layer and the first mask; and patterning the target layer using the hard-mask bar.

### CROSS-REFERENCE TO RELATED APPLICATIONS

This application is based on and claims priority under 35 U.S.C. § 119 to Korean Patent Application No. 10-2023-0102286, filed Aug. 4, 2023, and Korean Patent Application No. 10-2024-0025304, filed Feb. 21, 2024, in the Korean Intellectual Property Office, the disclosures of which are incorporated by reference herein in their entireties.

### BACKGROUND

Embodiments of the inventive concept relate to a method of manufacturing a semiconductor apparatus. More particularly, embodiments of the inventive concept relate to a method of manufacturing a semiconductor device, the method including a double-patterning process.

According to the goals for reduced sizes, multi-functionality, and high performance of electronic products, high capacity and high integration of semiconductor apparatus have been required. According to the high integration of semiconductor apparatuses, critical dimensions (CD) of patterns formed on semiconductor substrates have been reduced. Accordingly, there has been suggested a process of forming fine patterns on semiconductor substrates, e.g., a double patterning process.

### SUMMARY

Embodiments of the inventive concept provide a method of manufacturing a semiconductor apparatus, the method including contracting a photoresist pattern by using ion injection or plasma-doping.

Benefits and advantages of embodiments of the inventive concept are not limited thereto, and benefits and advantages not mentioned above may be clearly understood to those skilled in the art based on the following descriptions.

According to an aspect of the inventive concept, there is provided a method of manufacturing a semiconductor apparatus, the method including forming a target layer, a bottom mask layer, and a photoresist pattern, on a substrate, contracting the photoresist pattern, forming a mandrill bar on the first mask by using the photoresist pattern that is contracted, forming a conformal spacer layer on the first mask and the mandrill bar, etching the spacer layer, such that at least a portion of the first mask is free of the spacer layer, forming a sacrificial layer on the at least the portion of the first mask, forming a hard-mask bar by etching the spacer layer and the first mask, and patterning the first target layer by using the hard-mask bar.

According to another aspect of the inventive concept, there is provided a method of manufacturing a semiconductor apparatus, the method including forming a target layer, a bottom mask layer including a first mask, and a photoresist pattern, on a substrate, contracting the photoresist pattern, forming a mandrill bar on the first mask using the photoresist pattern that is contracted, forming a conformal spacer layer on the first mask and the mandrill bar, etching the spacer layer, such that at least a portion of a top surface of the mandrill bar and at least a portion of the first mask are free of the spacer layer, etching the mandrill bar, such that at least a portion of the first mask is free of the mandrill bar, forming a sacrificial layer on the at least the portion of the first mask that is free of the mandrill bar, forming a hard-mask bar by etching the spacer layer and the first mask, and patterning the target layer using the hard-mask bar.

According to another aspect of the inventive concept, there is provided a method of manufacturing a semiconductor apparatus, the method including forming a target layer, a bottom mask layer including a first mask, and a photoresist pattern, on a substrate, contracting the photoresist pattern, forming a mandrill bar on the first mask using the photoresist pattern that is contracted, forming a conformal spacer layer on the first mask and the mandrill bar, etching the spacer layer, such that at least a portion of the first mask is free of the spacer layer, forming a sacrificial layer on the at least the portion of the first mask that is free of the spacer layer, forming a hard-mask bar by etching the spacer layer and the first mask, and patterning the target layer using the hard-mask bar, wherein the contracting of the photoresist pattern comprises performing at least once injecting ions into the photoresist pattern, performing plasma-doping on the photoresist pattern, or a combination thereof.

### BRIEF DESCRIPTION OF THE DRAWINGS

Embodiments will be more clearly understood from the following detailed description taken in conjunction with the accompanying drawings in which:

FIGS. 1A and 1B are diagrams illustrating a process of injecting ions into a photoresist pattern, according to an embodiment;

FIG. 2 is a diagram illustrating contraction of a photoresist pattern by using an ion injection process, according to descriptions given with reference to FIG. 1A and/or FIG. 1B;

FIGS. 3 to 9 are diagrams schematically illustrating a method of manufacturing a semiconductor device, according to an embodiment;

FIG. 10 is a diagram illustrating a process of performing plasma-doping on a photoresist pattern, according to an embodiment;

FIG. 11 is a diagram illustrating contraction of a photoresist pattern by using a plasma doping process, according to descriptions given with reference to FIG. 10;

FIGS. 12 to 19 are diagrams schematically illustrating a method of manufacturing a semiconductor device, according to an embodiment; and

FIG. 20 is an image illustrating contraction of a photoresist pattern through a method of manufacturing a semiconductor device according to an embodiment.

### DETAILED DESCRIPTION OF THE EMBODIMENTS

Hereinafter, embodiments of the inventive concept will be described in detail with reference to the accompanying drawings. The same reference numerals will be given to the same components in the drawings, and repeated descriptions thereof will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

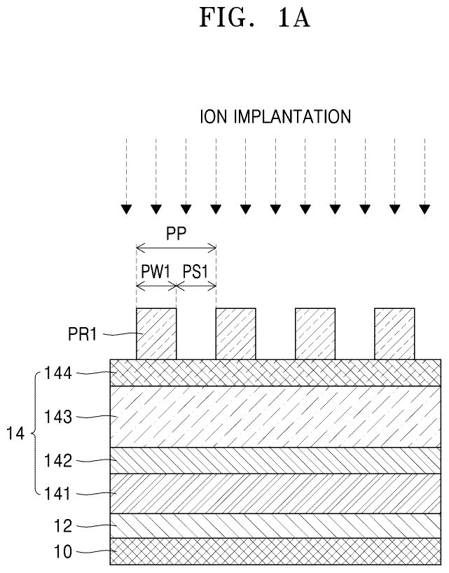

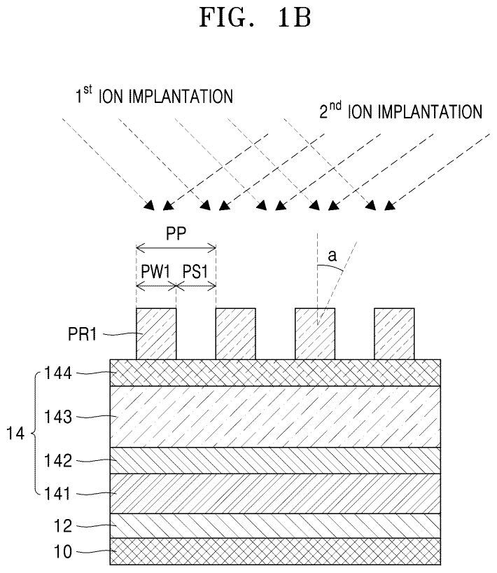

FIGS. 1A and 1B are diagrams illustrating a process of injecting ions into a photoresist pattern, according to an embodiment.

Referring to FIG. 1A, a method of manufacturing a semiconductor device, according to an embodiment, may include forming a target layer 12 and a bottom mask layer 14 on a substrate 10. A photoresist pattern PR1 may be formed on the bottom mask layer 14.

The substrate 10 may include a semiconductor such as Si or Ge, or a compound semiconductor such as SiGe, SiC, GaAs, InAs, or InP. In some embodiments, the substrate 10 may include one or more Group III-V materials or one or more Group IV materials or combinations thereof. In some embodiments, the substrate 10 may have a silicon-on-insulator (SOI) structure. The substrate 10 may include a conductive region, e.g., a well doped with impurities or a structure doped with impurities.

The target layer 12 may include a material layer to be finally patterned. For example, the target layer 12 may include a conductor, such as tungsten (W), ruthenium (Ru), titanium (TiN), or combinations thereof. However, the target layer 12 is not limited thereto and may include a metal material or a non-metal material in other embodiments.

The bottom mask layer 14 may include a first mask 141, a second mask 142, a third mask 143, and an anti-reflection film 144. The first mask 141, the second mask 142, the third mask 143, and the anti-reflection film 144 may be sequentially stacked on the target layer 12. In this case, the bottom mask layer 14 may include a hard-mask.

In some embodiments, the first mask 141, the second mask 142, and the third mask 143 may each include a silicon-containing material, such as silicon oxide, silicon oxynitride, silicon nitride, tetraethyl orthosilicate (TEOS), amorphous silicon, or polycrystalline silicon, a carbon-containing material, such as an amorphous carbon layer (ACL), or a metal, such as a spin-on hard-mask (SOH), or combinations thereof.

For example, the first mask 141 may include amorphous silicon, the second mask 142 may include silicon nitride, and the third mask 143 may include SOH but embodiments are not limited thereto. The anti-reflection film 144 may include silicon oxynitride (SiON) and may be formed by a chemical vapor deposition (CVD) process and the like but embodiments are not limited thereto.

The photoresist pattern PR1 may be formed on the bottom mask layer 14. The photoresist pattern PR1 may be formed by using a photoresist device. For example, the photoresist pattern PR1 may be formed by patterning a photoresist layer (not shown). In this case, the photoresist pattern PR1 may be formed by using an extreme ultraviolet (EUV, 13.5 mm) laser. However, embodiments of the photoresist pattern PR1 are not limited thereto and may also be formed by using a KrF excimer laser (248 nm), an ArF excimer laser (193 nm), or an F2 excimer laser (157 nm).

In some embodiments, the photoresist pattern PR1 formed by using a photoresist device may have a pitch of 36 nm. For example, a photoresist pitch PP may be 36 nm. A width PW1 of the photoresist pattern PR1 may be 18 nm, and a space PS1 between the photoresist patterns PR1 may be 18 nm. Hereinafter, for convenience of explanation, the photoresist pattern PR1 formed at a pitch of 36 nm will be mainly described. However, the embodiments are not limited thereto, the photoresist pitch PP may be formed to be 36 nm or greater.

Although the method of manufacturing a semiconductor apparatus, according to an embodiment, is described with reference to self-aligned double patterning (SADP), embodiments of the inventive concept are not limited thereto and a multi-patterning process, e.g., self-aligned quadruple patterning (SAQP) or self-aligned triple patterning (SATP) may be used.

The method of manufacturing a semiconductor apparatus, according to an embodiment, may contract the photoresist pattern PR1. For example, the photoresist pattern PR1 may be contracted by injecting ions into the photoresist pattern PR1. In this case, the ions may be injected in a direction parallel to the longitudinal direction of the photoresist pattern PR1.

In some embodiments, a process of injecting ions into the photoresist pattern PR1 may be performed at least once and may be repeated. The process of injecting ions into the photoresist pattern PR1 may be separated into a plurality of operations, and in each operation, the ions may be injected in a direction parallel to the longitudinal direction of the photoresist pattern PR1.

For example, the process of injecting ions into the photoresist pattern PR1 may be separated into n operations. In each operation, the substrate 10 may be rotated by 360/n°. After rotating the substrate 10 by 360/n°, the ions may be injected into the photoresist pattern PR1. In this case, the ions may be injected in a direction parallel to the longitudinal direction of the photoresist pattern PR1. The process of rotating the substrate 10 and the process of injecting ions into the photoresist pattern PR1 after rotating the substrate 10 may each be performed n times to rotate the substrate 10 a full 360°. By repeatedly performing the process of rotating the substrate 10 and the process of injecting the ions, the ions may be uniformly injected into the photoresist pattern PR1.

Referring to FIG. 1B, the method of manufacturing a semiconductor apparatus, according to an embodiment, may include contracting the photoresist pattern PR1. For example, the photoresist pattern PR1 may be contracted by injecting ions into the photoresist pattern PR1. In this case, the ions may be injected in a direction inclined by a selected or certain angle a with reference to the longitudinal direction of the photoresist pattern PR1. In this case, the selected or certain angle a may be in a range from about −90° to about 90°.

To inject the ions in a direction inclined by the selected or certain angle a with reference to the longitudinal direction of the photoresist pattern PR1, an ion beam may be scanned at the selected or certain angle a onto the photoresist pattern PR1, as shown in FIG. 1B. However, the embodiments are not limited to. Although not shown in FIG. 1B, a selected or certain angle may be formed between the ion beam and the photoresist pattern PR1 by inclining the substrate 10.

In some embodiments, the process of injecting ions into the photoresist pattern PR1 may be performed at least once and may be repeated. The process of injecting ions into the photoresist pattern PR1 may be separated into a plurality of operations, and in each operation, the ions may be injected in a direction inclined by a selected or certain angle with reference to the longitudinal direction of the photoresist pattern PR1. In this case, although the angle at which the ions are injected into the photoresist pattern PR1 may be different in different ones of the plurality of operations, the embodiments are not limited thereto.

For example, the process of injecting ions into the photoresist pattern PR1 may be separated into n operations. In each operation, the substrate 10 may be rotated by 360/n°. After rotating the substrate 10 by 360/n°, the ions may be injected into the photoresist pattern PR1. In this case, the ions may be injected in the direction inclined by the selected or certain angle a. The process of rotating the substrate 10 and the process of injecting ions into the photoresist pattern PR1 after rotating the substrate 10 may each be performed n times.

By repeatedly performing the process of rotating the substrate 10 and the process of injecting the ions, the ions may be more uniformly injected into the photoresist pattern PR1. For example, as the ions are injected in a direction inclining by the selected or certain angle (a) with reference to the longitudinal direction of the photoresist pattern PR1, a blind spot, into which the ions are not injected, may be generated. According to an embodiment, as the process of rotating the substrate 10 and the process of injecting the ions are repeatedly performed, the ions may be injected into the photoresist pattern PR1 without a blind spot.

In some embodiments, B, BFx, As, P, C, Ar, Si, Ge, H, or Xe ions or a combination thereof may be injected at least once. However, elements injected into the photoresist pattern PR1 are not limited to the aforementioned elements. In addition, the ions may be injected into the photoresist pattern PR1 in a dose in a range from about 1E12 ions/cm² to about 1E17 ions/cm². In addition, the ions may be injected into the photoresist pattern PR1 with ion injection energy of about 0.1 keV to about 60 keV. Furthermore, in some embodiments, in the process of injecting ions into the photoresist pattern PR1, a temperature of the substrate 10 may be in a range from about −100° C. to about 300° C.

In some embodiments, the process of injecting ions into the photoresist pattern PR1 may include a method of injecting ions in a direction parallel to the longitudinal direction of the photoresist pattern PR1, a method of injecting ions in a direction inclined by the selected or certain angle a with reference to the longitudinal direction of the photoresist pattern PR1, or a combination thereof. For example, when ions are injected n times into the photoresist pattern PR1, in some operations, the ions may be injected in a direction parallel to the longitudinal direction of the photoresist pattern PR1, and in other operations, the ions may be injected in a direction inclined by the selected or certain angle a with reference to the longitudinal direction of the photoresist pattern PR1.

In some embodiments, when ions are injected n times into the photoresist pattern PR1, according to the operations, different ions may be injected into the photoresist pattern PR1 during different ones of the n operations. In addition, the doses and the ion injection energy of the ions injected into the photoresist pattern PR1 may be different according to the different operations but embodiments are not limited thereto.

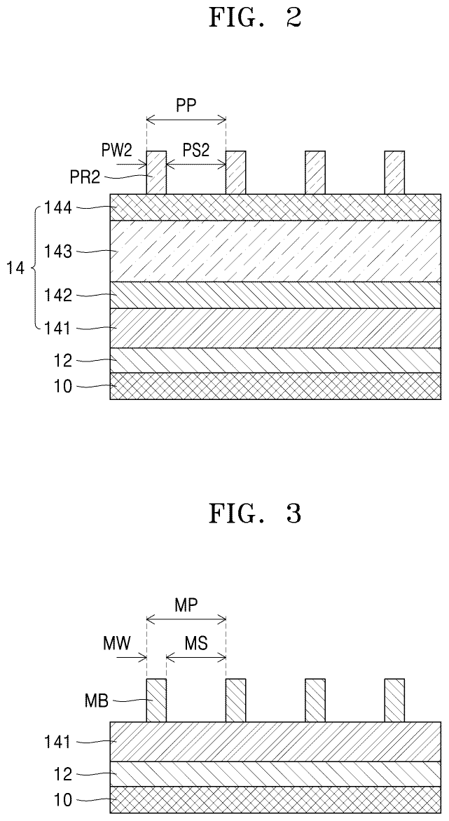

FIG. 2 is a diagram illustrating contraction of the photoresist pattern PR1 by using the ion injection process, according to the descriptions given with reference to FIG. 1A and/or FIG. 1B.

Referring to FIG. 2, by injecting the ions into the photoresist pattern PR1 (see FIGS. 1A and 1B), the photoresist pattern PR1 may be contracted. A width PW2 of a contracted photoresist pattern PR2 may be less than a width PW1 (see FIGS. 1A and 1B) of the photoresist pattern PR1 before ion injection. The width PW2 of the contracted photoresist pattern PR2 after ion injection may be several nanometers (nms) less than the width PW1 of the photoresist pattern PR1 before ion injection.

For example, the photoresist pitch PP before ion injection may be 36 nm. In this case, the width PW1 of the photoresist pattern PR1 may be 18 nm and a space PS1 between the photoresist patterns PR1 may be 18 nm. As the photoresist pattern PR1 is contracted due to ion injection, the width PW2 of the contracted photoresist pattern PR2 after ion injection may be 14 nm or less. In this case, as the photoresist pitch PP is constant, a space PS2 between a plurality of the contracted photoresist patterns PR2 may increase up to 18 nm or more.

In some embodiments, by forming the contracted photoresist pattern PR2 by using the ion injection process, etch burdens may be reduced or prevented. As the space PS2 between the contracted photoresist pattern PR2 increases, an etch space may expand in a process of forming a mandrill bar MB (see FIG. 3) to be described below. As the etch space expands, collapse of a bottom mask, which may occur when forming the mandrill bar by using existing photoresist patterns, may be mitigated or prevented.

In some embodiments, by injecting the ions into the photoresist pattern PR1, the durability of the contracted photoresist pattern PR2 may be improved. In addition, line edge roughness (LER) and line width roughness (LWR) of the contracted photoresist pattern PR2 may also be improved.

FIGS. 3 to 9 are diagrams schematically illustrating a method of manufacturing a semiconductor device, according to an embodiment.

Referring to FIG. 3, the method of manufacturing a semiconductor apparatus, according to an embodiment, may include forming a mandrill bar MB on a first mask 141 by using the contracted photoresist pattern PR2.

The mandrill bar MB may be formed on the first mask 141. In this case, at least a region in the mandrill bar MB may be formed in a line shape by using a photolithography process and an etching process.

The mandrill bar MB may be patterned by using the contracted photoresist pattern PR2 (see FIG. 2), the third mask 143, and the anti-reflection film 144. The mandrill bar MB may be formed by etching a portion of the second mask 142. The mandrill bar MB may include a material identical to a material included in the second mask 142. For example, the mandrill bar MB may be formed of \ amorphous silicon, polysilicon, silicon nitride, silicon oxide, or a combination thereof. After forming the mandrill bar MB, the contracted photoresist pattern PR2, the third mask 143, and the anti-reflection film 144 may be removed.

The mandrill bar MB may be formed by etching the second mask 142 using the contracted photoresist pattern PR2 as an etch mask. In this case, a width MW of the mandrill bar MB may be equal to the width PW2 of the contracted photoresist pattern PR2 or less. When the width PW2 of the contracted photoresist pattern PR2 is 14 nm, the width MW of the mandrill bar MB may be 14 nm or less. For example, the width MW of the mandrill bar MB may be 9 mm.

By forming the mandrill bar MB using the contracted photoresist pattern PR2, a space MS between a plurality of the mandrill bars MB may be secured. By stably securing the space MS between mandrill bars MB, a fine pattern P (see FIG. 9) to be described below may be stably formed.

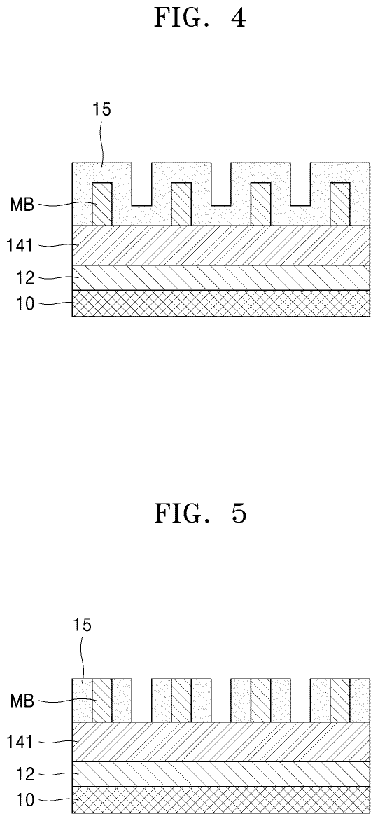

Referring to FIG. 4, the method of manufacturing a semiconductor apparatus, according to an embodiment, may include forming a spacer layer 15 on the first mask 141 and the mandrill bar MB. In this case, the spacer layer 15 may include, but is not limited to, silicon oxide.

The spacer layer 15 may conformally cover the first mask 141 and the mandrill bar MB. The spacer layer 15 may include a first horizontal portion at least partially covering the first mask 141, a second horizontal portion at least partially covering a top surface of the mandrill bar MB, and a vertical portion at least partially covering a side surface of the mandrill bar MB. The spacer layer 15 may be substantially and conformally formed through connection of the first horizontal portion, the second horizontal portion, and the vertical portion.

Referring to FIG. 5, the method of manufacturing a semiconductor apparatus, according to an embodiment, may include etching the spacer layer 15, such that the first mask 141 is at least partially exposed. The first mask 141 may be at least partially exposed by etching a portion of the first horizontal portion of the spacer layer 15. In this case, the second horizontal portion of the spacer layer 15 may also be etched, and the top surface of the mandrill bar MB may be at least partially exposed. In this case, a width of an exposed portion of the first mask 141 may be substantially equal to the width MW (see FIG. 3) of the mandrill bar MB.

Referring to FIG. 6, the method of manufacturing a semiconductor apparatus, according to an embodiment, may include forming a sacrificial layer 16 on the first mask 141 that has been at least partially exposed. In this case, the sacrificial layer 16 may include, but is not limited to, SOH.

The sacrificial layer 16 may conformally at least partially cover the first mask 141 and the spacer layer 15. The sacrificial layer 16 may include a vertical portion at least partially covering a side surface of the spacer layer 15 and the top surface of the first mask 141, and a horizontal portion at least partially covering the top surface of the mandrill bar MB and the top surface of the spacer layer 15. The sacrificial layer 16 may be substantially and conformally formed due to connection between the vertical portion and the horizontal portion.

A width of the vertical portion of the sacrificial layer 16 may be substantially equal to the width MW of the mandrill bar MB. For example, when the width MW of the mandrill bar MB is 9 nm, the width of the vertical portion of the sacrificial layer 16 may also be 9 nm.

Referring to FIG. 9, the method of manufacturing a semiconductor apparatus, according to an embodiment, may include etching the sacrificial layer 16. More particularly, a horizontal portion of the sacrificial layer 16 may be etched. By etching the horizontal portion of the sacrificial layer 16, the top surface of the mandrill bar MB, the top surface of the spacer layer 15, and a top surface of the sacrificial layer 16 may be at least partially exposed.

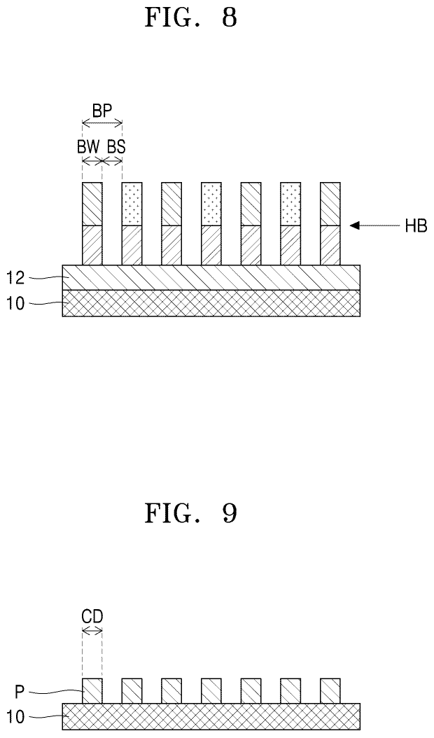

Referring to FIG. 8, the method of manufacturing a semiconductor apparatus, according to an embodiment, may include forming a hard-mask bar HB. The hard-mask bar HB may be formed by etching the spacer layer 15 and the first mask 141.

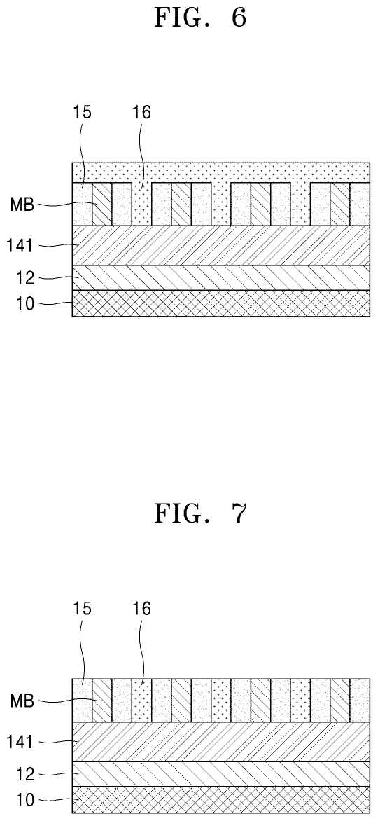

The hard-mask bar HB may be patterned by using the mandrill bar MB (see FIG. 7) and the sacrificial layer 16 (see FIG. 7). The hard-mask bar HB may be formed by etching a portion of the first mask 141.

The hard-mask bar HB may be formed by etching the first mask 141 and the spacer layer 15, using the mandrill bar Mb and the sacrificial layer 16 as etching masks. For example, the hard-mask bar HB may include a combination of the patterned first mask 141 and the mandrill bar MB. In addition, the hard-mask bar HB may include a combination of the patterned first mask 141 and the sacrificial layer 16.

In some embodiments, the width BW of the hard-mask bar HB may be equal to the width MW of the mandrill bar MB. For example, when the width MW of the mandrill bar MB is 9 nm, the width BW of the hard-mask bar HB may be 9 nm. In this case, a space BS between a plurality of the hard-mask bars HB may be 9 nm.

The method of manufacturing a semiconductor apparatus may include a pitch BP of the hard-mask bar HB of 18 nm. The width BW of the hard-mask bar HB may be 9 nm, and the space BS between the hard-mask bars HB may be 9 nm. For convenience of explanation, only the pitch BP of the hard-mask bar HB formed at 18 nm has been described. However, the pitch BP of the hard-mask bar HB is not limited thereto and may be formed to be 18 nm or greater in accordance with different embodiments.

Referring to FIG. 9, the method of manufacturing a semiconductor apparatus, according to an embodiment, may include patterning the target layer 12 (see FIG. 8) by using the hard-mask bar HB (see FIG. 8). By etching the target layer 12 by using the hard-mask bar HB as an etch mask, a fine pattern P may be formed on the substrate 10.

In this case, a critical dimension (CD) of the fine pattern P may be substantially equal to the width BW of the hard-mask bar HB (see FIG. 8). For example, when the width BW of the hard-mask bar HB is 9 nm, the CD of the fine pattern P may be 9 nm. In this case, a space between a plurality of the fine patterns P may be 9 nm. That is, the fine pattern P having a pitch of 18 nm may be formed. However, a pitch of the fine pattern P is not limited thereto and may be formed to be 18 nm or greater in accordance with different embodiments.

According to the related art, as the space PS1 (see FIGS. 1A and 1B) between the photoresist patterns PR1 (see FIGS. 1A and 1B) is small, it may be difficult to form the mandrill bar MB (see FIG. 3). When it is difficult to form the mandrill bar MB, it may be difficult to form the fine pattern P on the substrate 10.

For example, when using a 36 nm-pitch exposure device, which is generally the limit of an extreme ultraviolet exposure device in the related art, the space PS1 between the photoresist patterns PR1 is 18 nm. As the space PS1 between the photoresist patterns PR1 is small (e.g., 18 nm or less), it may be difficult to form the mandrill bar MB, and as a result, it may be difficult to form the fine pattern P having a CD of 9 nm.

According to some embodiments of the method of manufacturing a semiconductor apparatus, the contracted photoresist patterns PR2 (see FIG. 2) may be formed by using an ion injection process to secure the space PS2 (see FIG. 2) between the contracted photoresist patterns PR2. Due to the increase in the space PS2 between the contracted resist patterns PR2, an etching space may be stably secured and the mandrill bar MB (see FIG. 3) may be stably formed with less likelihood of problems, such as etch burdens. The hard-mask bar HB may be formed by forming the mandrill bars MB and securing the space MS between the mandrill bars MB. Next, the fine pattern P may be stably formed by using the hard-mask bar HB.

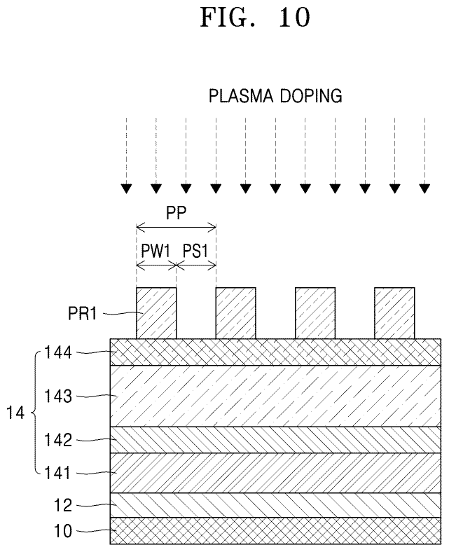

FIG. 10 is a diagram illustrating a process of performing plasma-doping on the photoresist pattern, according to an embodiment. Hereinafter, regarding the descriptions of FIGS. 10 to 19, the same descriptions previously made with respect to FIGS. 1 to 9 will be omitted.

Referring to FIG. 10, the method of manufacturing a semiconductor apparatus, according to an embodiment, may include forming the target layer 12 and the bottom mask layer 14 on the substrate 10. The photoresist pattern PR1 may be formed on the bottom mask layer 14. The photoresist pattern PR1 may be formed by using a photoresist device. For example, the photoresist pattern PR1 may be formed by patterning a photoresist layer (not shown). In this case, the photoresist pattern PR1 may be formed by using extreme ultraviolet (EUV, 13.5 mm) laser. However, the photoresist pattern PR1 is not limited thereto and may also be formed by using a KrF excimer laser (248 nm), an ArF excimer laser (193 nm), and an F2 excimer laser (157 nm) in other embodiments.

The method of manufacturing a semiconductor apparatus, according to an embodiment, may include contracting the photoresist pattern PR1. For example, the photoresist pattern PR1 may be contracted by performing plasma-doping on the photoresist pattern PR1. In this case, B₂H₆, BF₃, PH₃, AsH₃, CₓH_{y}, CₓO_{y}, SiₓH_{y}, BₓH_{y}, BₓF_{y}, PₓH_{y}, AsₓH_{y}, GeₓF_{y} (where x and y are integers), or combinations thereof may be used as a source gas of the plasma, but the embodiments are not limited thereto.

In some embodiments, in a process of performing plasma-doping on the photoresist pattern PR1, the photoresist pattern PR1 may be doped with the source gases in a dose in a range from about 1E12 ions/cm² to about 1E17 ions/cm². In addition, the photoresist pattern PR1 may be doped with the source gases having a doping energy of about 0.1 keV to about 15 kcV. Furthermore, in some embodiments, in the process of performing plasma-doping on the photoresist pattern PR1, the temperature of the substrate 10 may be in the range from about 100° C. to about 300° C.

In some embodiments, the process of performing plasma-doping on the photoresist pattern PR1 may be performed at least once and may be repeated. The process of performing plasma-doping on the photoresist pattern PR1 may be divided into a plurality of operations, and plasma-doping may be performed on the photoresist pattern PR1 in each operation.

In some embodiments, in the process of performing plasma-doping on the photoresist pattern PR1, the plasma-doping may be performed at least one using at least one recipe. For example, plasma-doping may be performed one or more times using a recipe. In addition, plasma-doping may be performed several times using a plurality of recipes. In this case, at least some of the plurality of recipes may be different from one another, but the embodiments are not limited thereto.

In some embodiments, in the process of performing plasma-doping on the photoresist pattern PR1, a plurality of source gases may be sequentially used. The process of performing plasma-doping on the photoresist pattern PR1 may be performed a plurality of times by sequentially using the source gases such as B₂H₆, BF₃, PH₃, or AsH₃, CₓH_{y}, CₓO_{y}, SiₓH_{y}, BₓH_{y}, BₓF_{y}, PₓH_{y}, AsₓH_{y}, GeₓF_{y} (where x and y are integers).

In some embodiments, the process of performing plasma-doping on the photoresist pattern PR1 may include controlling radicals of the plasma. In the process of performing plasma-doping on the photoresist pattern PR1, a direction in which the radicals of the plasma move may be controlled. For example, the radicals may be controlled to be doped on the photoresist pattern PR1 without being introduced to the substrate 10. However, the embodiments are not limited thereto, and the photoresist pattern PR1 may be doped with plasma without controlling the radicals.

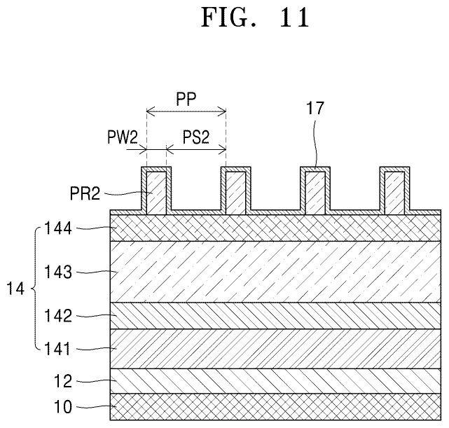

FIG. 11 is a diagram illustrating contraction of the photoresist pattern PR1 by using a plasma-doping process, according to the descriptions given with reference to FIG. 10.

Referring to FIG. 11, the photoresist pattern PR1 may be contracted by performing plasma-doping on the photoresist pattern PR1 (see FIG. 10). The width PW2 of the contracted photoresist pattern PR2 may be less than the width PW1 (see FIG. 10) of the photoresist pattern PR1 before plasma-doping. The width PW2 of the contracted photoresist pattern PR2 after plasma-doping may be several nanometers (nms) less than the width PW1 of the photoresist pattern PR1 before plasma-doping.

For example, the photoresist pitch PP before plasma-doping may be 36 nm. In this case, the width PW1 of the photoresist pattern PR1 may be 18 nm, and the space PS1 between the photoresist patterns PR1 may be 18 nm. As the photoresist pattern PR1 is contracted due to plasma-doping, the width PW2 of the contracted photoresist pattern PR2 after plasma-doping may be 14 nm or less. In this case, as the photoresist pitch PP is constant, the space PS2 between the plurality of the contracted photoresist patterns PR2 may increase up to 18 nm or more.

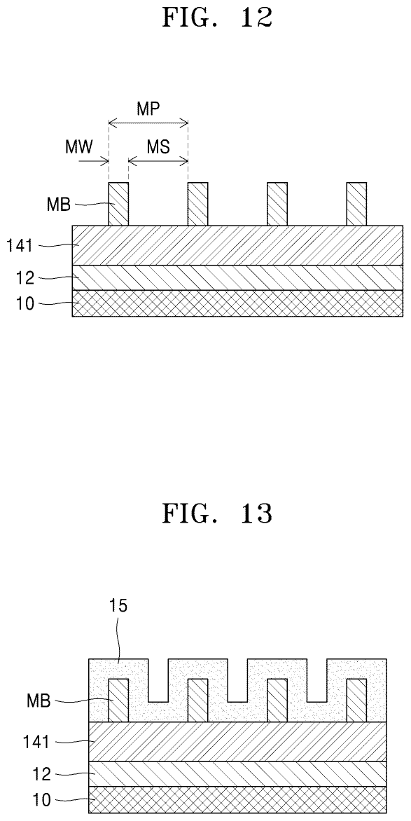

In some embodiments, by forming the contracted photoresist pattern PR2 by using the plasma-doping process, etch burdens may be reduced or prevented. As the space PS2 between the contracted photoresist patterns PR2 increases, an etch space may expand in a process of forming the mandrill bar MB (see FIG. 12) to be described below. As the etching space expands, collapse of a bottom mask, which may occur when forming the mandrill bar by using existing photoresist patterns, may be prevented or the likelihood of occurrence may be reduced.

In some embodiments, by performing the plasma-doping on the photoresist pattern PR1, the durability of the contracted photoresist pattern PR2 may be improved. In addition, LER and LWR of the contracted photoresist pattern PR2 also be improved.

After plasma-doping, according to process conditions, a thin-film layer 17 at least partially covering the contracted photoresist pattern PR2 may be formed. According to the process conditions, the thin-film layer 17 at least partially covering the contracted photoresist pattern PR2 may be not formed. In this case, the thin-film layer 17 may include boron (B) oxide, phosphide (P) oxide, arsenide (As) oxide, and the like. The thin-film layer 17 may be removed by an etching process in the following process of forming the mandrill bar MB. In addition, the thin-film layer 17 may also be removed by additional processes of ashing and strip, and the following process of forming the mandrill bar MB may be performed.

FIGS. 12 to 19 are diagrams each schematically illustrating a method of manufacturing a semiconductor device, according to an embodiment.

Referring to FIG. 12, the method of manufacturing a semiconductor apparatus, according to an embodiment, may include forming the mandrill bar MB on the first mask 141 by using the contracted photoresist pattern PR2.

The mandrill bar MB may be formed on the first mask 141. In this case, at least region in the mandrill bar MB may be formed in a line shape by using a photolithography process and an etching process.

The mandrill bar MB may be patterned by using the contracted photoresist pattern PR2 (see FIG. 11), the third mask 143, and the anti-reflection film 144. The mandrill bar MB may be formed by etching a portion of the second mask 142. The mandrill bar MB may include a material identical to a material included in the second mask 142. For example, the mandrill bar MB may be formed of amorphous silicon, polysilicon, silicon nitride, silicon oxide, or combinations thereof. After forming the mandrill bar MB, the contracted photoresist pattern PR2, the third mask 143, and the anti-reflection film 144 may be removed.

The mandrill bar MB may be formed by etching the second mask 142 using the contracted photoresist pattern PR2 as an etch mask. In this case, the width MW of the mandrill bar MB may be equal to the width PW2 of the contracted photoresist pattern PR2 or less. When the width PW2 of the contracted photoresist pattern PR2 is 14 nm, the width MW of the mandrill bar MB may be 14 nm or less. For example, the width MW of the mandrill bar MB may be 9 mm.

By forming the mandrill bar MB using the contracted photoresist pattern PR2, the space MS between a plurality of the mandrill bars MB may be secured. By stably securing the space MS between the mandrill bars MB, the fine pattern P (see FIG. 19) to be described below may be securely formed.

Referring to FIG. 13, the method of manufacturing a semiconductor apparatus, according to an embodiment, may include forming the spacer layer 15 on the first mask 141 and the mandrill bar MB. In this case, the spacer layer 15 may include, but is not limited to, silicon oxide.

The spacer layer 15 may conformally at least partially cover the first mask 141 and the mandrill bar MB. The spacer layer 15 may include the first horizontal portion at least partially covering the first mask 141, the second horizontal portion at least partially covering the top surface of the mandrill bar MB, and the vertical portion at least partially covering the side surface of the mandrill bar MB. The spacer layer 15 may be substantially and conformally formed through connection of the first horizontal portion, the second horizontal portion, and the vertical portion.

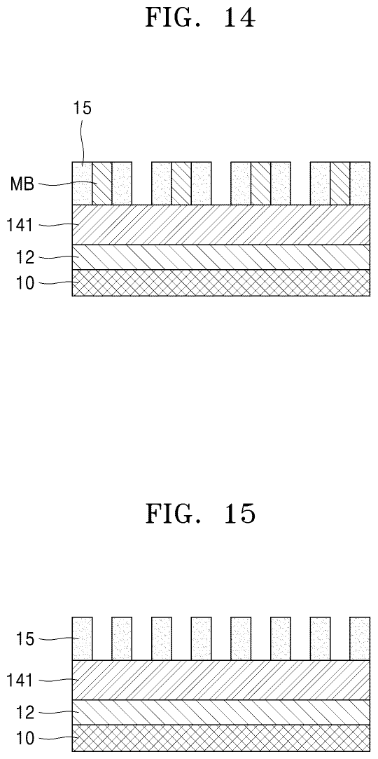

Referring to FIG. 14, the method of manufacturing a semiconductor apparatus, according to an embodiment, may include etching the spacer layer 15 to expose at least a portion of the first mask 141. The first mask 141 may be exposed in part by etching a portion of the first horizontal portion of the spacer layer 15. Here, the second horizontal portion of the spacer layer 15 may also be etched, and the top surface of the mandrill bar MB may be exposed at least in part. In this case, the width of the portion through which the first mask 141 is exposed may be substantially equal to the width MW (see FIG. 13) of the mandrill bar MB.

Referring to FIG. 15, the method of manufacturing a semiconductor apparatus, according to an embodiment, may include removing the mandrill bar MB. The mandrill bar MB may be etched such that the first mask 141 is at least partially exposed. In this case, the width of the portion through which the first mask 141 is at least partially exposed may be substantially equal to the width MW (see FIG. 13) of the mandrill bar MB. As the mandrill bar MB is removed, only the spacer layer 15 that has been patterned may remain on the first mask 141.

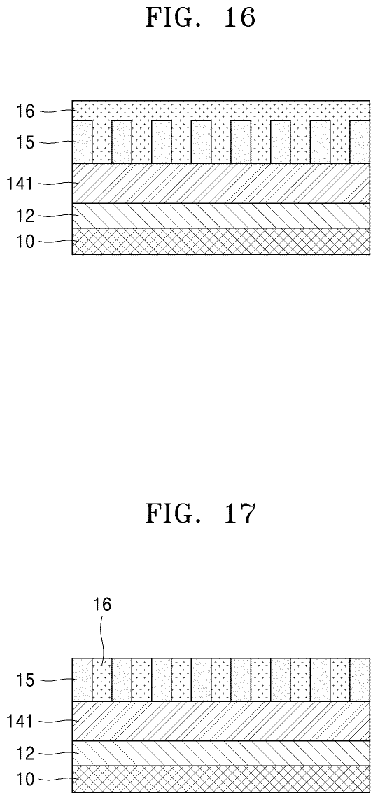

Referring to FIG. 16, the method of manufacturing a semiconductor apparatus, according to an embodiment, may include forming the sacrificial layer 16 on the first mask 141 that has been at least partially exposed and the spacer layer 15 that has been patterned. In this case, the sacrificial layer 16 may include, but is not limited to, SOH.

The sacrificial layer 16 may conformally at least partially cover the first mask 141 and the spacer layer 15. The sacrificial layer 16 may include the vertical portion at least partially covering the side surface of the spacer layer 15 and the top surface of the first mask 141, and the horizontal portion at least partially covering the top surface of the spacer layer 15. The sacrificial layer 16 may be substantially and conformally formed through connection between the vertical portion and the horizontal portion.

The width of the vertical portion of the sacrificial layer 16 may be substantially equal to the width MW (see FIG. 12) of the mandrill bar MB. For example, when the width MW of the mandrill bar MB is 9 nm, the width of the vertical portion of the sacrificial layer 16 may be 9 nm.

Referring to FIG. 17, the method of manufacturing a semiconductor apparatus, according to an embodiment, may include etching the sacrificial layer 16. More particularly, the horizontal portion of the sacrificial layer 16 may be etched. By etching the horizontal portion of the sacrificial layer 16, the top surface of the spacer layer 15 and the top surface of the sacrificial layer 16 may be at least partially exposed.

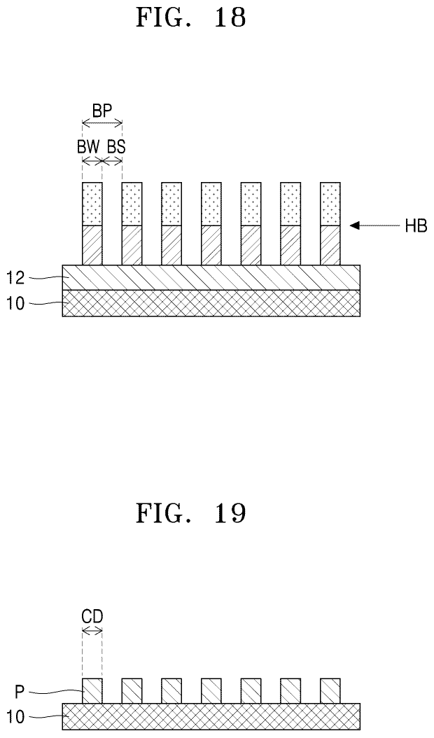

Referring to FIG. 18, the method of manufacturing a semiconductor apparatus, according to an embodiment, may include forming the hard-mask bar HB. The hard-mask bar HB may be formed by etching the spacer layer 15 and the first mask 141. The hard-mask bar HB may be patterned using the sacrificial layer 16 (see FIG. 17). The hard-mask bar HB may be formed by etching a portion of the first mask 141.

The hard-mask bar HB may be formed by etching the first mask 141 and the spacer layer 15, using the sacrificial layer 16 as an etching mask. For example, the hard-mask bar HB may include a combination of the patterned first mask 141 and the sacrificial layer 16.

In some embodiments, the width BW of the hard-mask bar HB may be equal to the width of the vertical portion of the sacrificial layer 16. For example, when the width of the vertical portion of the sacrificial layer 16 is 9 nm, the width BW of the hard-mask bar HB may be 9 nm. In this case, the space BS between the plurality of the hard-mask bars HB may be 9 nm.

The method of manufacturing a semiconductor apparatus may include forming the pitch BP of the hard-mask bar HB at 18 nm. The width BW of the hard-mask bar HB may be 9 nm, and the space BS between the hard-mask bars HB may be 9 nm. For convenience of explanation, only the pitch BP of the hard-mask bar HB of 18 nm has been described, the pitch BP of the hard-mask bar HB is not limited thereto and may be formed to be 18 nm or greater in accordance with different embodiments.

Referring to FIG. 19, the method of manufacturing a semiconductor apparatus, according to an embodiment, may include patterning the target layer 12 (see FIG. 18) by using the hard-mask bar HB (see FIG. 18). By etching the target layer 12 by using the hard-mask bar HB as an etch mask, the fine pattern P may be formed on the substrate 10.

In this case, a CD of the fine pattern P may be substantially equal to the width BW (see FIG. 18) of the hard-mask bar HB. For example, when the width BW of the hard-mask bar HB is 9 nm, the CD of the fine pattern P may be 9 nm. In this case, a space between a plurality of the fine patterns P may be 9 nm. That is, the fine pattern P having an 18 nm pitch may be formed. However, the pitch of the fine pattern P is not limited thereto and may be formed to be 18 nm or greater in accordance with different embodiments.

The method operations of manufacturing a semiconductor device described with reference to FIGS. 1 to 9 and the method operations of manufacturing a semiconductor device described with reference to FIGS. 10 to 19 may be shared between each other. For example, a process of forming the contracted photoresist patter PR2 through the ion injection process and then etching the mandrill bar MB (see FIGS. 15 to 18) may be performed. In addition, a process of forming the contracted photoresist pattern PR2 through the plasma-doping process and then forming the hard-mask bar HB without etching the mandrill bar MB (see FIGS. 5 to 8) may be performed.

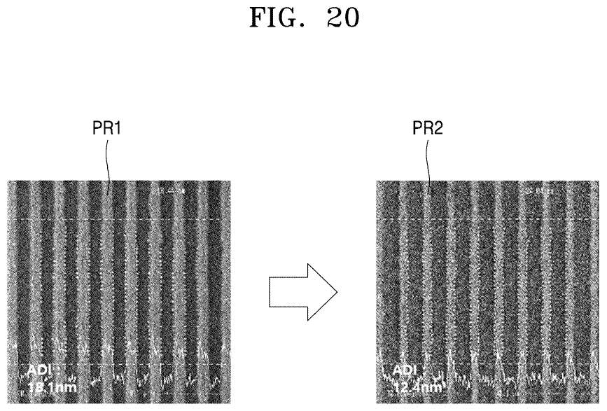

FIG. 20 is an image illustrating contraction of the photoresist pattern PR1 through a method of manufacturing a semiconductor device according to an embodiment.

Referring to FIG. 20, it is found that the width PW1 of the photoresist pattern PR1 is 18.1 nm. The contracted photoresist pattern PR2 may be formed by performing the ion injection process or the plasma-doping process on the photoresist pattern PR1. It is found that the width PW2 of the contracted photoresist pattern PR2 may be 12.4 nm.

In some embodiments, a combination of the ion injection process and the plasma-doping process may be performed to form the contracted photoresist pattern PR2. In this case, the order of operations and/or the number of times that the ion injection process and/or the plasma-doping process are performed may be variously designed according to requirements. For example, a first ion injection process, a first plasma doping process, and a second ion injection process may be sequentially performed. In addition, as another example, the first plasma-doping process, the first ion injection process, a second plasma-doping process, and the second ion-injection process may be sequentially formed.

The method of manufacturing a semiconductor apparatus may include forming the contracted photoresist pattern PR2 (see FIGS. 2 and 11) by using the ion injection process and/or the plasma-doping process. Accordingly, the space PS2 between the contracted photoresist patterns PR2 may be secured to be relatively wide. Due to the increase in the space PS2 between the contracted photoresist pattern PR2, an etching space may be stably secured, and the mandrill bar MB (see FIGS. 3 and 12) may be stably formed without problems, such as etch burdens. The hard-mask bar HB may be formed by forming the mandrill bars MB and securing the space MS between the mandrill bars MB. Next, the fine pattern P may be stably formed by using the hard-mask bar HB.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor apparatus, comprising:
forming a target layer, a bottom mask layer comprising a first mask, and a photoresist pattern, on a substrate;
contracting the photoresist pattern;
forming a mandrill bar on the first mask by using the photoresist pattern that is contracted;
forming a conformal spacer layer on the first mask and the first mandrill bar;
etching the spacer layer, such that at least a portion of the first mask is free of the spacer layer;
forming a sacrificial layer on the at least the portion of the first mask;
forming a hard-mask bar by etching the spacer layer and the first mask; and
patterning the target layer by using the hard-mask bar.

2. The method of claim 1, wherein the contracting of the photoresist pattern comprises:
injecting ions into the photoresist pattern; or
performing plasma-doping on the photoresist pattern; or
injecting the ions into the photoresist pattern and performing the plasma-doping on the photoresist pattern.

3. The method of claim 2, wherein the injecting of the ions into the photoresist pattern comprises injecting the ions in a direction parallel to a longitudinal direction of the photoresist pattern.

4. The method of claim 2, wherein the injecting of the ions into the photoresist pattern comprises injecting the ions in a direction inclined at an angle with reference to a longitudinal direction of the photoresist pattern.

5. The method of claim 4, wherein the angle is in a range from about −90 to about 90°.

6. The method of claim 2, wherein the injecting of the ions into the photoresist pattern further comprises
rotating the substrate by 360/n°; and
injecting the ions into the photoresist pattern after the rotating of the substrate by 360/n°;
performing the rotating and the injecting n times.

7. The method of claim 2, wherein the injecting of the ions into the photoresist pattern comprises injecting B, BFx, As, P, C, Ar, Si, Ge, H, or Xe ions or a combination thereof at least once.

8. The method of claim 2, wherein, in the performing of plasma-doping on the photoresist pattern, B₂H₆, BF₃, PH₃, AsH₃, CₓH_{y}, CₓO_{y}, SiₓH_{y}, BₓH_{y}, BₓF_{y}, PₓH_{y}, AsₓH_{y}, GeₓF_{y}, where x and y are integers, or a combination thereof is used as source gas of the plasma.

9. The method of claim 2, wherein the performing of plasma-doping on the photoresist pattern comprises performing the plasma-doping at least once using at least one recipe.

10. The method of claim 2, further comprising removing a thin-film layer formed during the performing of plasma-doping on the photoresist pattern.

11. The method of claim 1, wherein the contracting of the photoresist pattern comprises contracting a width of the photoresist pattern by several nm.

12. A method of manufacturing a semiconductor apparatus, comprising:
forming a target layer, a bottom mask layer comprising a first mask, and a photoresist pattern, on a substrate;
contracting the photoresist pattern;
forming a mandrill bar on the first mask by using the photoresist pattern that is contracted;
forming a conformal spacer layer on the first mask and the first mandrill bar;
etching the spacer layer, such that at least a portion of a top surface of the mandrill bar and at least a portion of the first mask are free of the spacer layer;
etching the mandrill bar, such that at least a portion of the first mask is free of the mandrill bar;
forming a sacrificial layer on the at least the portion of the first mask that is free of the mandrill bar;
forming a hard-mask bar by etching the spacer layer and the first mask; and
patterning the target layer by using the hard-mask bar.

13. The method of claim 12, wherein the contracting of the photoresist pattern comprises:
injecting ions into the photoresist pattern; or
performing plasma-doping on the photoresist pattern; or
injecting the ions into the photoresist pattern and performing the plasma-doping on the photoresist pattern.

14. The method of claim 13, wherein the injecting of the ions into the photoresist pattern comprises injecting B, BFx, As, P, C, Ar, Si, Ge, H, or Xe ions or a combination thereof at least once.

15. The method of claim 13, wherein, in the performing of plasma-doping on the photoresist pattern, B₂H₆, BF₃, PH₃, AsH₃, CₓH_{y}, CₓO_{y}, SiₓH_{y}, BₓH_{y}, BₓF_{y}, PₓH_{y}, AsₓH_{y}, GeₓF_{y}, where x and y are integers, or a combination thereof is used as source gas of the plasma.

16. The method of claim 13, wherein the performing of plasma-doping on the photoresist pattern comprises performing the plasma-doping at least once using at least one recipe.

17. A method of manufacturing a semiconductor apparatus, comprising:
forming a target layer, a bottom mask layer comprising a first mask, and a photoresist pattern, on a substrate;
contracting the photoresist pattern;
forming a mandrill bar on the first mask by using the photoresist pattern that is contracted;
forming a conformal spacer layer on the first mask and the first mandrill bar;
etching the spacer layer, such that at least a portion of the first mask is free of the spacer layer;
forming a sacrificial layer on the at least the portion of the first mask that is free of the spacer layer;
forming a hard-mask bar by etching the spacer layer and the first mask; and
patterning the target layer by using the hard-mask bar,
wherein the contracting of the photoresist pattern comprises
injecting ions into the photoresist pattern, performing plasma-doping on the photoresist pattern, or performing a combination thereof at least once.

18. The method of claim 17, wherein the contracting of the photoresist pattern comprises repeating injecting the ions into the photoresist pattern, performing plasma-doping on the photoresist pattern, or a combination thereof.

19. The method of claim 17, wherein the injecting of the ions into the photoresist pattern comprises injecting B, BFx, As, P, C, Ar, Si, Ge, H, or Xe ions or a combination thereof at least once.

20. The method of claim 17, wherein the performing of plasma-doping on the photoresist pattern comprises controlling a direction of radicals of plasma.
